(19) United States
(12) Patent Application Publication
(10) Pub. No.: US 2010/0288356 A1
(43) Pub. Date: Nov. 18, 2010

(54) Photoactive compositions containing plasmon-resonating nanoparticles

(75) Inventors: Suljo Linic, Ann Arbor, MI (US); Phillip N. Christopher, Ann Arbor, MI (US); David B. Ingram, Ann Arbor, MI (US)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: The Regents of the University of Michigan, Ann Arbor, MI (US)

(21) Appl. No.: 12/800,294

(22) Filed: May 12, 2010

Related U.S. Application Data
(60) Provisional application No. 61/177,518, filed on May 12, 2009.

(51) Int. Cl. H01L 31/0216; H01L 31/0232

(52) U.S. Cl. 136/256; 257/432; 257/E31.12; 257/E31.127

(57) ABSTRACT

Disclosed herein are photoactive compositions that include a semiconductor and plasmon-resonating nanoparticles that are capable of concentrating light at a wavelength that is substantially the same as the wavelength of light necessary to promote an electron from a valance band to a conduction band in the semiconductor. As such, the plasmon-resonating nanoparticles direct light to the band gap of the semiconductor at an increased intensity (relative to when such nanoparticles are not present). And because of that increased intensity, the photoactive composition can be more efficiently used to catalyze a photochemical reaction or generate electrical potential in a photovoltaic cell.

### CROSS-REFERENCE TO RELATED APPLICATION

Priority under 35 U.S.C. §119(e) to U.S. provisional patent application Ser. No. 61/177,518 filed May 12, 2009, the entire contents of which are incorporated herein by reference, is claimed.

### STATEMENT OF GOVERNMENTAL INTEREST

This invention was made with governmental support under grants from the U.S. Department of Energy, Office of Basic Energy Sciences (DOE-BES) and Division of Chemical Science (FG-02-05ER15686), and the National Science Foundation (CBET0756255). The government has certain rights in the invention.

### BACKGROUND OF THE INVENTION

1. Field of the Disclosure

The disclosure generally relates to compositions containing a semiconductor and plasmon-resonating nanoparticles capable of concentrating light at a wavelength sufficient to promote an electron from a valance band to a conduction band in the semiconductor. Accordingly, the compositions provide new and powerful platforms for photocatalytic reactions, any chemical reactions that involve photocatalytic steps, and the formation of photovoltaics.

2. Brief Description of Related Technology

Generally, a photochemical reaction is a chemical reaction induced by light. The efficient use of natural sunlight in these reactions has been a long-standing research focus because these reactions can advance energetically-efficient and environmentally-friendly chemical transformations. For example, photochemical reactions are used in solar cells to harvest solar energy across the solar spectrum. Thus, more efficient photochemical reactions in this context will likely lead to more efficient collection of solar energy.

Photocatalysis is the acceleration of a photochemical reaction in the presence of a catalyst. Titanium dioxide (TiO₂, titania) is an example of such a catalyst, and is available in three forms (rutile, anatase, and brookite), the anatase form of which is most common for photocatalysis. As a photocatalyst, titanium dioxide can be used in the production of energy and in the remediation of wastewater. For example, titanium dioxide can be used to catalyze the water-gas shift reaction, and to catalyze hydrolysis. The products of these reactions can be used to generate energy or other useful products. Titanium dioxide also can be used to catalyze reactions that detoxify or otherwise remediate wastewater.

Titanium dioxide behaves as a photocatalyst under ultraviolet (UV) light. Unfortunately, the wide band gap of titanium dioxide (3.2 eV for the anatase phase) limits its use as a photocatalyst because light from the ultraviolet region of the electromagnetic spectrum is required for its activation. Because UV light represents only a small fraction of solar light, research in this art has been concerned with shifting the optical response of titanium dioxide towards the visible light region of the spectrum, which accounts for a much higher fraction of solar light. This research has concluded that shifting the optical response of titanium dioxide from UV light towards visible light increases opportunities to use the material. The art has, therefore, developed various techniques and identified various dopants for doping titanium dioxide. See generally, Burda U.S. patent application publication No. US 2006/0210798 A1, the disclosure of which is incorporated herein by reference. Accordingly, when doped, titanium dioxide behaves as a photocatalyst under visible and UV light.

But the use of titanium dioxide, and other photocatalysts for that matter, is somewhat limited to the efficiency of the catalyst to absorb light. And this efficiency is limited whether the photocatalyst is doped or undoped. One response in the art is to use greater amounts of such catalysts. But even that response has its limits in the context of photoreactive processes, such as, for example, the limited ability of light to penetrate a (thick) layer of the photocatalyst, and the limited photocatalyst surface area on which the light can act. Generally, the art does not sufficiently teach or suggest how to improve the efficiency of photocatalysts (doped or undoped). Increased efficiencies, of course, would result in concomitant improvements in photoreactive processes, which would in turn lead to improvements in a variety of systems dependent upon photochemical reactions.

### SUMMARY OF THE INVENTION

Disclosed herein are photoactive compositions that provide efficiencies lacking in the prior art. Accordingly, the disclosed photoactive compositions address long-felt needs in the art and is theorized herein, by reference to representative experiments (e.g., decomposition of methylene blue, and oxidation of carbon monoxide), to provide marked improvements in photoreactive processes.

Generally, embodiments of the photocatalyst composition include a semiconducting photocatalyst and plasmon-resonating nanoparticles. The plasmon-resonating nanoparticles are capable of concentrating light at a wavelength that is substantially the same as the wavelength of light necessary to promote an electron from a valance band to a conduction band in the semiconductor. As such, the plasmon-resonating nanoparticles direct light to the band gap of the semiconductor at an increased intensity (relative to when such nanoparticles are not present). And because of that increased intensity, the photocatalyst can be more efficiently used to catalyze a photochemical reaction.

Additional features of the invention may become apparent to those skilled in the art from a review of the following detailed description, taken in conjunction with the drawings, the examples, and the appended claims.

### BRIEF DESCRIPTION OF THE DRAWING FIGURES

The patent or application file contains at least one drawing executed in color. Copies of this patent or patent application publication with color drawing(s) will be provided by the Office upon request and payment of the necessary fee.

For a more complete understanding of the disclosure, reference should be made to the following detailed description and accompanying drawing figures wherein:

FIG. 1 is a graphical representation of the rate of decomposition of methylene blue in air when utilizing three different compositions in accordance with the invention and in contrast to a photocatalyst not according to the invention, specifically a photocatalyst composition lacking plasmon-resonating nanoparticles;

FIG. 2 is a graphical representation of the rate of decomposition of methylene blue in air when utilizing three different compositions in accordance with the invention and in contrast to a photocatalyst not according to the invention, specifically a photocatalyst composition lacking plasmon-resonating nanoparticles, where the amount of silver was standardized at 15 wt. % across all composite compositions;

FIG. 3 is a graphical representation of the optical absorbance spectra of silver nanospheres, nanowires, and nanocubes, and a graphical representation of the rate constant of methylene blue decomposition plotted as a function of the silver plasmon intensity at the source wavelengths of different shapes and densities of the silver nanostructure;

FIG. 4 is a graphical representation of the simulated scattering efficiency in the region of 400-500 nm as a function of particle size for silver nanocubes and nanospheres, the diffuse reflectance of semiconductors and photoactive compositions according to this disclosure, and the kinetic date for methylene blue decomposition under visible light, 400-900 nm at 50 mW/cm²;

FIG. 5 is a color photograph and a graphical representation of the effect of nanocube size on the plasmon resonance wavelength;

FIG. 6 is a graphical representation of the oxidation of carbon monoxide over a temperature range when utilizing a photocatalyst composition not according to the invention, specifically a photocatalyst composition lacking plasmon-resonating nanoparticles;

FIG. 7 is a graphical representation of the oxidation of carbon monoxide over a temperature range when utilizing a photocatalyst composition according to the invention;

FIG. 8 is a graphical representation of the oxidation of carbon monoxide over a temperature range when utilizing a photocatalyst composition according to the invention;

FIG. 9 is a graphical representation of the oxidation of carbon monoxide over a temperature range when utilizing a non-photocatalyst composition; and,

FIG. 10 is a graph displaying the data shown in each of FIGS. 6 through 9.

While the disclosed compositions are susceptible of embodiments in various forms, there are illustrated in the examples and figures (and will hereafter be described) specific embodiments of the compositions, with the understanding that the disclosure is intended to be illustrative, and is not intended to limit the invention to the specific embodiments described and illustrated herein.

### DETAILED DESCRIPTION OF THE INVENTION

The invention generally relates to catalyst compositions. Specifically, the invention relates to photocatalyst and photovoltaic compositions that include a semiconductor and plasmon-resonating nanoparticles. As described in further detail herein, the plasmon-resonating nanoparticles are capable of concentrating light at a wavelength that is substantially the same as the wavelength of light necessary to promote an electron from a valance band to a conduction band in the semiconductor.

As used herein, “nanoparticle” generally refers to a particle that exhibits one or more properties not normally associated with a corresponding bulk material (e.g., quantum optical effects, etc.). The term also generally refers to materials having at least two dimensions that do not exceed about 1000 nm. And, in various embodiments described herein, these dimensions are even smaller. As is understood by those of ordinary skill in the art, the term nanoparticles refers explicitly to the crystalline core material, herein preferably copper, silver and/or gold, and implicitly to the capping agent. The description of the size and/or shape of a nanoparticle refers to the crystalline core material unless otherwise designating the inclusion of a capping agent.

Recent developments in solution-based techniques have allowed for the synthesis of nanostructures with well-controlled, highly-uniform sizes, and particle geometries. Some of these nanostructures (e.g., metals with free-electron-like valence bands, such as noble metals) exhibit a strong localized surface plasmon resonance (LSPR) due to the nanometer scale spatial confinement, and the metal's inherent electronic structure. For example, the resonance frequency of silver (Ag) nanostructures falls in the ultraviolet to visible light range, and can be tuned by changing the geometry and size of the particles. The intensity of resonant electromagnetic radiation is enhanced by several orders of magnitude near the surface of plasmonic (or plasmon-resonating) nanoparticles. Disclosed herein are compositions that exploit the ability of plasmonic nanoparticles to concentrate electromagnetic fields to increase photon absorption in nearby semiconducting materials, thereby increasing photocatalytic reaction rates and photovoltaic efficiency.

Plasmon resonance is an optical phenomenon arising from the collective oscillation of conduction electrons in a metal when the electrons are disturbed from their equilibrium positions. Such a disturbance can be induced by an electromagnetic wave (light), in which the free electrons of a metal are driven by the alternating electric field to coherently oscillate at a resonant frequency relative to the lattice of positive ions. The plasmon frequencies for most metals occur in the UV region of the electromagnetic spectrum, with alkali metals and some transition metals such as copper, silver, and gold exhibiting plasmon frequencies in the visible region of that spectrum. A “plasmon-resonating” (or “plasmonic”) nanoparticle, therefore, is a nanoparticle having conduction electrons that collectively oscillate when disturbed from their equilibrium positions.

The frequency and intensity of a plasmon resonance are generally determined primarily by the intrinsic dielectric property of a given metal, the dielectric constant of the medium in contact with the metal, and the pattern of surface polarization. As such, any variation in the shape or size of a metal particle that can alter the surface polarization and causes a change to the plasmon resonance. This dependence offers the ability to tune the surface plasmon resonance, or localized surface plasmon resonance (LSPR) of metal nanoparticles through shape-controlled synthesis. Such synthesis are generally described in Lu et al. (2009) Annu. Rev. Phys. Chem. 60:167-92, the disclosure of which is incorporated herein by reference.

The plasmon-resonating nanoparticles can have any shape, but generally and preferably have a shape that is spherical (nanospheres), cube shape (nanocubes), or wire shape (nanowires). In a preferred embodiment, the plasmon-resonating nanoparticles have a cube shape (nanocubes). The shapes of these plasmon-resonating nanoparticles can be obtained by various nanoparticle synthesis methods such as, for example, those described in Xia et al. U.S. patent application publication No. US 2005/0056118 A1.

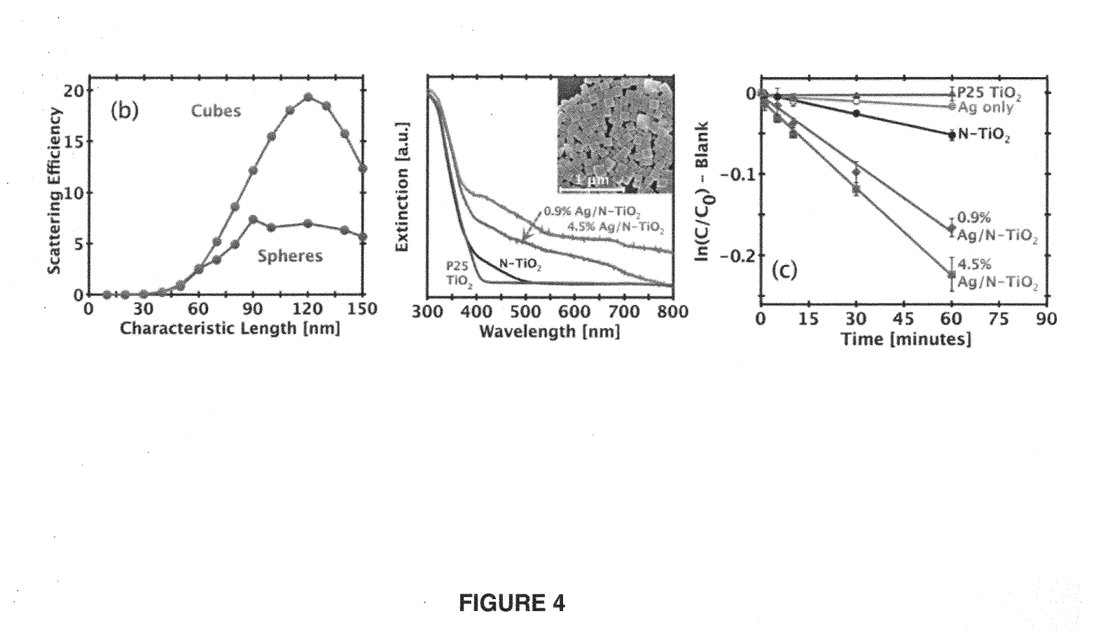

In each of these shapes, the plasmon-resonating nanoparticle will have an effective diameter, which as used herein is the smallest cross-section of the plasmon-resonating nanoparticle or the plasmon-resonating portion thereof, e.g., a plasmon-resonating layer. Thus, for example, the effective diameter of a plasmon-resonating nanowire is determined based on the smallest cross-section of the nanowire, for example, as measured by TEM. Further, the effective diameter of a plasmon-resonating nanosphere will coincide with and be the same as the diameter of the nanosphere. Generally, the plasmon-resonating nanoparticles should have an effective diameter of about 10, 20, 30, 40, 50, 60, 70, 80, 90, 100 nm to about 100, 110, 120, 130, 140, 150, 160, 170, 180, 190, 200 nm, preferably about 30 nm to about 170 nm, more preferably about 30 nm to about 100 nm. In the context of a plasmon-resonating nanocube, the nanocube will have an effective diameter coincident with the cube edge-length and of about 10 nm to about 200 nm; preferably about 90 nm to about 150 nm when the semiconductor absorbs light in a range of about 400-500 nm. See FIG. 4. Generally, the wavelength of light plasmon-resonated by the nanoparticles will vary with the size and shape of the nanoparticles. For example, the larger the plasmon-resonating nanoparticle within these ranges, the greater the wavelength of light affected.

In various embodiments, the light can be ultraviolet light (10 nm to 380 nm), visible light (380 nm to 780 nm), or infrared light (780 nm to 1000 μm).

In various embodiments, the plasmon-resonating nanoparticles include at least one of copper, silver, and gold nanoparticles. These nanoparticles may include copper/silver/gold alloy nanoparticles (e.g., copper-silver nanoparticles, copper-gold nanoparticles, silver-gold nanoparticles, copper-silver-gold nanoparticles). These nanoparticles also may include, for example, silica as a core onto which the copper, silver and/or gold are deposited. In another variation, the plasmon-resonating nanoparticles can be particles of substrates, for example silica, platinum, or other metal particles, onto which a plasmon-resonating layer is deposited, e.g., layers of Cu, Ag, or Au. Alternatively, in less preferred embodiments, the nanoparticles may include a core constructed of the copper, silver and/or gold, with a layer of silica, for example, deposited onto the core. In one preferred embodiment, the nanoparticles include copper. In another preferred embodiment, the nanoparticles include gold. In yet another preferred embodiment, the nanoparticles include silver.

In a preferable embodiment, the plasmon-resonating nanoparticles further include non-conductive layers, e.g., non-conductive capping agents. Examples of non-conductive layers include, for example, the organic capping agents often employed to manufacture the nanoparticles. In one variation, the organic capping agent and therefore the non-conductive layer is an alkane thiol. In the preferred variations, the non-conductive layer provides a barrier to the hopping of an electron from the semiconductor conduction band to the nanoparticle.

The semiconductor can be doped or undoped. As explained herein, the composition can be designed to accommodate either a doped or an undoped semiconductor. The semiconductor is preferably selected from the group consisting of ZrO₂, KTaO₃, SrTiO₃, TiO₂, ZnO, ZnS, CdS, CdSe, CdTe, GaP, SiC, Si, MoS₂, WO₃, and Fe₂O₃. Preferably, the semiconductor is doped or undoped titanium dioxide (TiO₂), herein the designation of TiO₂ includes undoped (undoped-TiO₂), p-doped (p-TiO₂), and n-doped (n-TiO₂) TiO₂ semiconductors. The semiconductor can also be present in the shape and size of nanoparticles (e.g., materials having nanometer-sized dimensions that do not exceed about 1000 nm). In another variation, the semiconductor can be present as a thin film, a highly porous thin film, an aerogel, or a xerogel.

The semiconductor and the plasmon-resonating nanoparticles are generally present in the photoactive composition in a mass ratio to one another of about 4:1 to about 100:1, preferably, about 5:1 to about 25:1, and more preferably about 8:1 to about 10:1. The photoactive composition can contain about 1, 5, 10, or 15 wt. % plasmon-resonating nanoparticles in the photoactive composition.

In one embodiment, the semiconductor is in direct contact with the plasmon-resonating nanoparticles, preferably in direct contact with the non-conductive layer of the nanoparticles. This is possible in embodiments wherein pre-fabricated semiconductors are deposited onto the plasmon-resonating nanoparticles and are not expected to wet surfaces of the plasmon-resonating nanoparticles. In these embodiments, there is very little shift in the plasmon resonance. Further, this provides the ability to fine tune plasmon-resonating nanoparticles—by size and shape, for example—to accommodate different semiconductors (whether doped or undoped). Additional embodiments include, but are not limited to, admixing pre-fabricated semiconductor and plasmon-resonating nanoparticles then depositing the admixture on a substrate, layer-by-layer deposition of the pre-fabricated semiconductor and plasmon-resonating nanoparticles on a substrate, adsorption of a dispersion of plasmon-resonating nanoparticles by a porous semiconductor, and synthesis (e.g., sol-gel deposition) of the semiconductor from an admixture of semiconductor precursors and plasmon-resonating nanoparticles.

In accordance with the invention, the plasmon-resonating nanoparticles are capable of concentrating light at a wavelength that is substantially the same as the wavelength of light necessary to promote an electron from a valance band to a conduction band in the semiconductor (regardless of whether the semiconductor is doped). Preferably, the plasmon-resonating nanoparticles are capable of concentrating light at a wavelength that is the same as the wavelength of light necessary to promote an electron from a valance band to a conduction band in the semiconductor. As used herein in this context, the term “substantially the same as” refers to a wavelength that is within about ±10%, preferably about ±5%, and more preferably about ±3% of the wavelength of light necessary to at promote an electron from a valence band to a conduction band in the semiconductor. As indicated above, however, in a most preferred embodiment, the term refers to a wavelength that is the same as the wavelength of light necessary to promote an electron from a valance band to a conduction band in the semiconductor.

The semiconductor, for example titanium dioxide, can be used as a support. But, in various other embodiments, a support independent of the semiconductor and independent of the plasmon-resonating nanoparticles can be used. Generally, suitable support materials can be any material that does not, for example, adversely affect the reaction intended to be catalyzed by the photocatalyst composition. Further, suitable supports can be any material that does not detrimentally affect (e.g., cause deactivation or decomposition of) the composition or its components. Suitable such supports include, but are not limited to, silica, silicates, alumina, aluminates, titinates, zirconates, carbon, carbonates, carbides, diatomaceous earth, glass, glass wool, quartz, carborundum, or ion-exchanged zeolites.

When the photoactive composition is used as a photovoltaic the support is preferably a conductive material. Suitable conductive supports include, but are not limited to, conductive oxides (e.g., indium oxides and tin oxides), conductive metals (e.g., aluminum, titanium, tin, zinc, silver, copper, nickel, and alloys thereof), conducting polymers (e.g, polycarbonates, poly(3-hexylthiophene), poly(p-phenylene vinylene), poly(9,9′-dioctylfluorene-co-benzothiadiazole) (“F8BT”), poly(9,9′-dioctylfluorene-co-bis-N,N′-(4-butylphenyl)-bis-N,N′-phenyl-1,4-phenylenediamine), poly(9,9′-dioctylfluorene-co-bis-N,N′-(4-butylphenyl)diphenylamine) (“TFB”), poly(4,4′-oxydiphenylene-pyromellitimide) (“Kapton”), polyethylene terephthalate (e.g., “Mylar”), poly(paraphenylene terephthalamide) (e.g., “Kevlar”), polyacetylenes, and mixtures thereof), and combinations thereof.

In embodiments wherein the photoactive composition in used as a photovoltaic material, a photovoltaic cell typically further includes an antireflective coating or texturing, a front contact, a rear contact, and leads. The rear contact is often reflective and comprosed of the support material. The front contact is often a transparent conductor (e.g., conducting polymers) or a grid of opaque or somewhat opaque materials (e.g., conductive metal). The front contact and the rear contact are, separately, electrically connected to the photoactive composition. The photovoltaic cell may further include an electrolyte, for example a conductive liquid or gel that is transparent and preferably does not chemically react with the photoactive composition.

### EXAMPLES

The following examples are provided to illustrate the invention, but are not intended to limit the scope thereof. Examples 1-3 describe the photocatalytic decomposition of methylene blue and contrasts the same using (a) photocatalytic compositions in accordance with the invention, (b) a photocatalytic composition that lacks a plasmon-resonating nanoparticle. Example 4 describes the oxidation of carbon monoxide and contrasts the same when using (a) photocatalytic compositions in accordance with the invention, (b) a photocatalytic composition that lacks a plasmon-resonating nanoparticle, and (c) a non-photocatalyst.

### Example 1

This example describes the decomposition of methylene blue and contrasts the same using (a) photocatalytic compositions in accordance with the invention, (b) a photocatalytic composition that lacks a plasmon-resonating nanoparticle. The following materials were used to carry out this example: ethylene glycol (J. T. Baker item 9300, purity is such that the concentration of chlorine ions (Cl⁻) is less than one part per million (ppm) and iron concentration (Fe) is less than 0.01 ppm); AgNO₃ (99% purity, Sigma Aldrich cat. No. 209139); Polyvinylpyrrolidone (PVP) 55,000 M.W. (Sigma Aldrich cat. No. 856568); Concentrated hydrochloric acid (HCl); 20 mL glass vials; Magnetic stir bars (cleaned with either piranha solution or with Alconox and successive sonication in water, ethanol and acetone); and a Syringe pump.

Silver nanostructures of various shapes can be formed generally by the reduction of silver nitrate with ethylene glycol in the presence of PVP. The morphology and dimensions of the product depend on reaction conditions, including temperature, the concentration of silver nitrate, and the molar ratio between the repeating unit of PVP and silver nitrate. The methods described below provide nanostructures with high uniformity in sizes, controllable size and shape, single crystallinity, large quantities, and good dispersibility in variable solvents.

Nanoparticle cubes were prepared by adding 5 mL ethylene glycol and a magnetic stir bar to a 20 mL vial and submerging the vial in an oil bath heated to 140° C. to 145° C. on a stirring hotplate. The cap to the vial was loosely placed on top to allow boiling off of vapors from any contaminant solvent. One hour was allowed for heating. After one hour of heating, three other solutions were prepared. The first solution was 6 mL of 0.1 M silver nitrate (AgNO₃) in ethylene glycol. This solution was shaken vigorously for two to three minutes to ensure all of the silver nitrate was dissolved into solution. The second solution was 0.15 M PVP (in terms of repeating unit) in 6 mL ethylene glycol; once again, the solution was vigorously shaken to ensure dissolution. Lastly a stock solution of 30 mM HCl in ethylene glycol was prepared (and was useable for up to a month for separate synthesis). Using a micropipette, 100 μL of the 30 mM HCl solution was added to the hot ethylene glycol. The solution was mixed for five to ten minutes. While waiting, the PVP and silver nitrate solutions were drawn into new 30 mL syringes. Once the solution had mixed, five to ten minutes after the HCl addition, 3 mL of silver nitrate and PVP solutions were added to the heated vial using a syringe pump at a rate of 0.75 mL/min. At this point the cap was loosely placed back on the vial, (one turn just to secure the cap). This solution was then allowed to react for a period of about 24 hours. During this period a combination of oxygen (from the air) and chlorine (from HCl) etching proceeded to generate single crystal silver (Ag) seeds. After 24 hours, the cap on the vial was tightened such that the vial became airtight. Over the next two to three hours a series of color changes were observed resulting in a thick tan/ocher colored solution. The size of these particles can be tuned by changing the amount of hydrochloric acid added to the system. For example, the above-mentioned procedure produced cubes of about 60 nm to 70 nm edge length. Decreasing the volume of 30 mM HCl added to the synthesis to 60 μL produced cubes of about 110 nm edge length.

The synthesis of nanowires was identical to the above-mentioned procedure for the preparation of nanocubes, except the incubation step was shortened to 5 hours, rather than 24 hours. The nanowire diameter was tuned using the hydrochloric acid concentration, just as in the nanocubes synthesis.

Nanoparticle spheres (nanospheres) were prepared by adding 5 mL of ethylene glycol and a magnetic stir bar to a 20 mL vial and submerging the vial in an oil bath heated to 150° C. to 155° C. on a stirring hotplate. The cap to the vial was loosely placed on top to allow boiling off of vapors from any contaminant solvent. One hour was allowed for heating. After one hour of heating, two other solutions were prepared. The first solution was 3 mL of 0.2 M silver nitrate in ethylene glycol. This solution was shaken vigorously for two to three minutes to ensure all of the silver nitrate was dissolved into solution. The second solution was 0.30 M PVP (in terms of repeating unit) in 3 mL ethylene glycol; once again, the solution was shaken vigorously to ensure dissolution. The silver and PVP solutions are then poured into the hot ethylene glycol. The solution was removed from the oil bath after one hour. Size was tuned by lowering the initial silver (Ag) concentration and by increasing the PVP concentrations in solution.

The silver nanoparticles (synthesized using the previously mentioned procedures) were concentrated by centrifugation and dispersed in 5 mL of ethanol. The solution was sonicated to re-disperse the silver particles in the ethanol and deposited on silicon substrates using a spin coating technique (4000 RPM). The amount of silver added was monitored using UV-Vis absorbance spectroscopy (Avantes AvaLight DHc light source and AvaSpec-2048 Fiber Optic Spectrometer) in a back scattering geometry. This synthesis sought to achieve a 0.5 monolayer coverage of the silver particles on the silicon wafer, meaning that half of the silicon surface area was covered by the silver particles. In order to directly compare the enhancement from different silver shapes, UV-Vis absorbance spectroscopy was used to ensure a similar absorbance from the three different silver films.

The industrial standard TiO₂ photocatalyst (Degussa P25, now commercially available from Evonik Industries (Essen, Germany) under the product name AEROXIDE® TiO₂ P 25) was dispersed in a separate ethanol solution and sonicated to ensure no particle agglomeration (0.05 g in 4 mL ethanol). Methylene Blue(MB) was then added to the solution, to reach a concentration of 100 mM and allowed to adsorb to the TiO₂ surfaces for 30 minutes. This solution was then added to the silver film by spin coating (50 μL of the solution at 4000 RPM). Following this, the substrates were allowed to completely dry in a dark environment for two hours. The decomposition of the MB was monitored using UV-Vis absorbance spectroscopy in a back scattering geometry. The photoactivity was induced using a 365 nm light source, and the decomposition of the MB was monitored every minute.

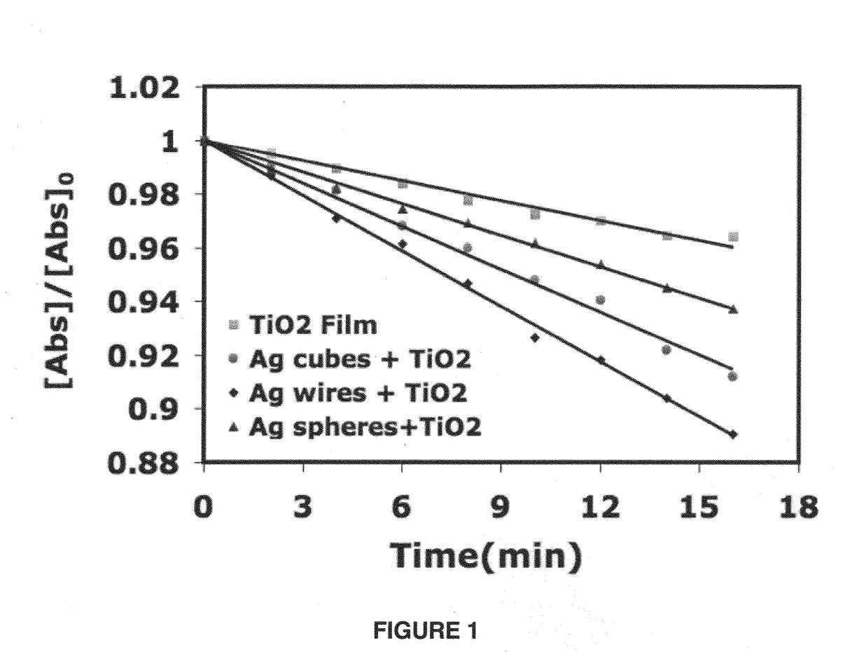

The results from batch MB decomposition experiments are shown in FIG. 1. The rate of reaction on the silver nanowires/TiO₂ composite was three times that of pure TiO₂. The nanocube system enhanced the rate two times and the spherical particles about 1.5 times.

The results also show that the plasmon resonance of the nanowires closely overlaps or matches the band gap of titanium dioxide. The effect is somewhat diminished here, where the shape of the nanoparticles was other than wires. This example demonstrates the importance of shape/geometry in matching the plasmon resonance of the nanoparticle to the band gap of the photocatalyst.

### Example 2

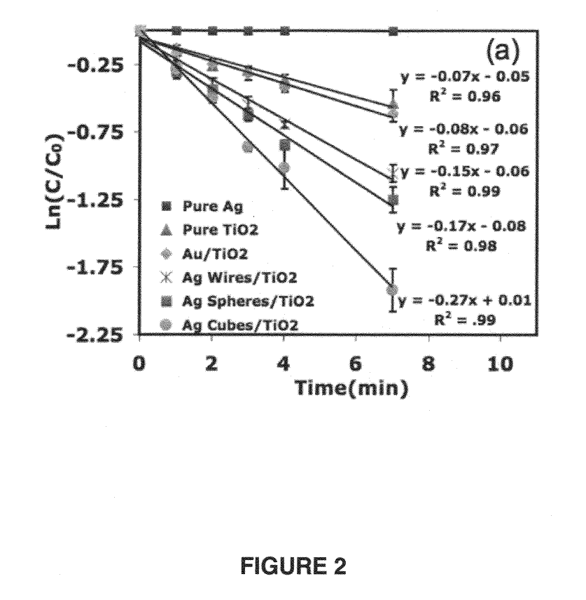

The procedure of Example 1 was repeated and the amount of silver deposited was standardized across all samples; all silver containing samples were 15 wt % silver in the photoactive Ag/TiO₂ composition. Kinetic data for the decomposition of methylene blue was performed with 365 nm UV light at 15 mW/cm². The results shown in FIG. 2 indicate significant rate enhancement for all silver nanocrystals, the silver wires and spheres performing approximately the same, while further enhancement by the silver nanocubes.

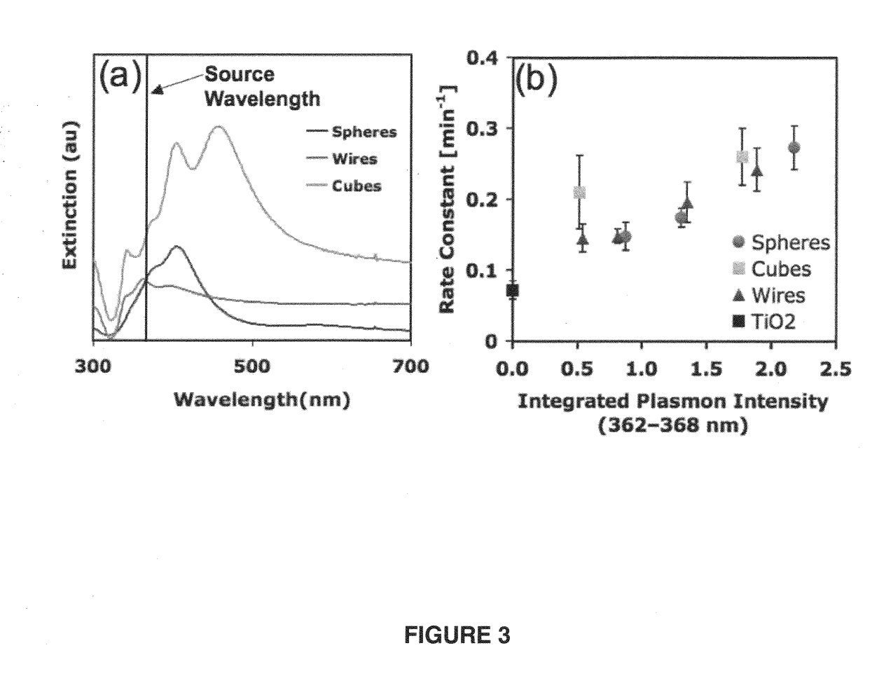

FIG. 3 illustrates the results of measurements made in Example 2 where the density (wt. %) of silver in a photoactive composition was varied. The variation in the rate constant for methylene blue decomposition as a function of the silver plasmon intensity for different shapes and densities of silver indicate a direct correlation between the rate enhancement and the plasmon intensity, FIG. 3(b). FIG. 3(a) illustrates the normalized plasmon intensities for silver nanospheres, nanowires, and nanocubes.

FIG. 4 illustrates the results of methylene blue decomposition studies at varying percentages of silver nanocubes. FIG. 4(a) illustrates the scattering efficiency of nanocubes and nanospheres as a function of effective diameter. FIG. 4(b) illustrates enhancements in the diffuse reflectivity when silver nanocubes are combined with n-doped TiO₂. These results further illustrate that the enhancement in the rate of methylene blue decomposition, and thereby the efficiency of the photochemical reaction, correlates to the size, the shape and the loading (density) of the nanoparticle in the photoactive composition, FIG. 4(c).

### Example 3

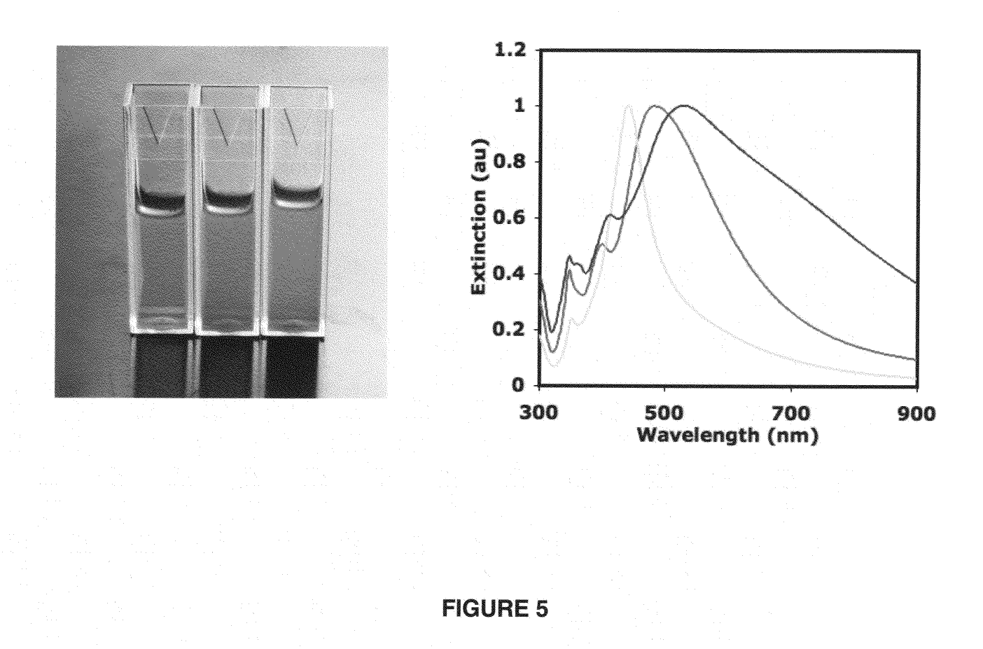

The extinction coefficients of a variety of silver nanocubes was measured. Nanocubes with effective diameters from about 50 to about 120 nm were observed under visible light and by optical spectroscopy. FIG. 5(a) shows the change in color of the nanocubes and FIG. 5(b) shows the optical spectra for the same nanocubes. These results illustrate that narrow or broad spectrum photoactive compositions can be made by varying the size of the nanocube, suggestive of the formation of photodetectors.

### Example 4

This example demonstrates the performance of embodiments of the photocatalyst composition in accordance with the invention in the context of oxidation of carbon monoxide. This example further contrasts that performance with that of a photocatalyst not according to the invention (specifically a photocatalyst composition lacking plasmon-resonating nanoparticles) and with that of a non-photocatalyst (silica).

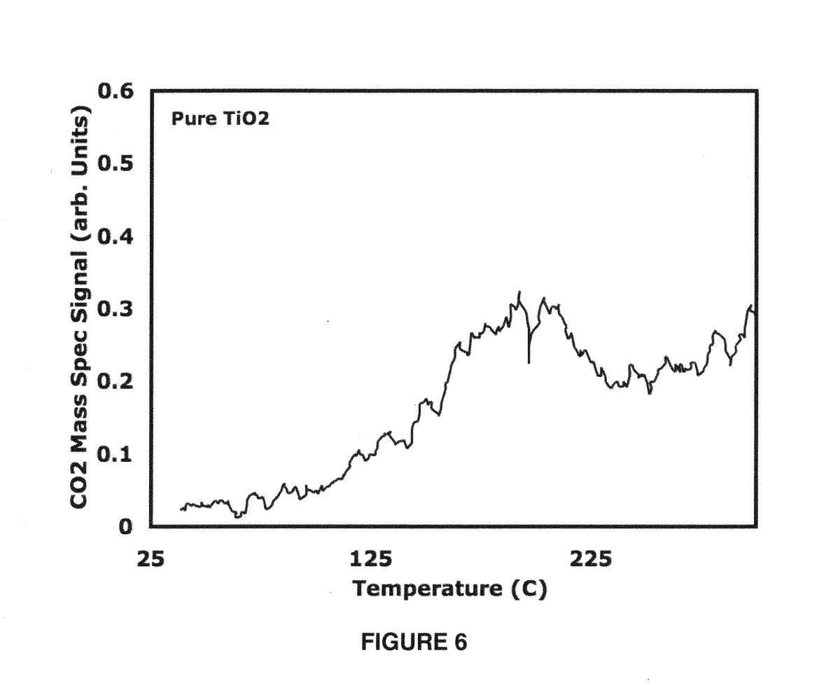

The experiments were run using a heated cell with a flat geometry and a quartz window for exposing the catalyst to UV light. Carbon monoxide (CO) and oxygen (O₂) (UHP gases at 25 SCCM) were bubbled through water (very little activity was noticed without water) in an equal molar ratio and passed over the catalyst. The temperature was steadily increased at a rate of five degrees per minute and all products were monitored using a Mass spectrometer. Molecular hydrogen (H₂) was not noticed at any point in any reaction, which indicated that a water gas shift reaction was not occurring. FIGS. 6 through 10, described in more detail below, graphically present the results from four experiments.

FIG. 6 graphically presents the oxidation of carbon monoxide over a temperature range when utilizing a photocatalyst composition not according to the invention, specifically a photocatalyst composition lacking plasmon-resonating nanoparticles. More specifically, pure TiO₂ was run with and without light to understand how UV-light is promoting the reaction. No carbon dioxide (CO₂) production was noticed until about 250° C. or 300° C. without light. When the experiment was re-run with fresh catalyst and light was added, a CO₂ peak is noticeable around 200° C., followed by a similar increase in CO₂ around 250° C. similar to the case without light. These peaks are illustrated in FIG. 2, which plots the carbon dioxide mass spectrometry signal in arbitrary units versus reaction temperature (° C.).

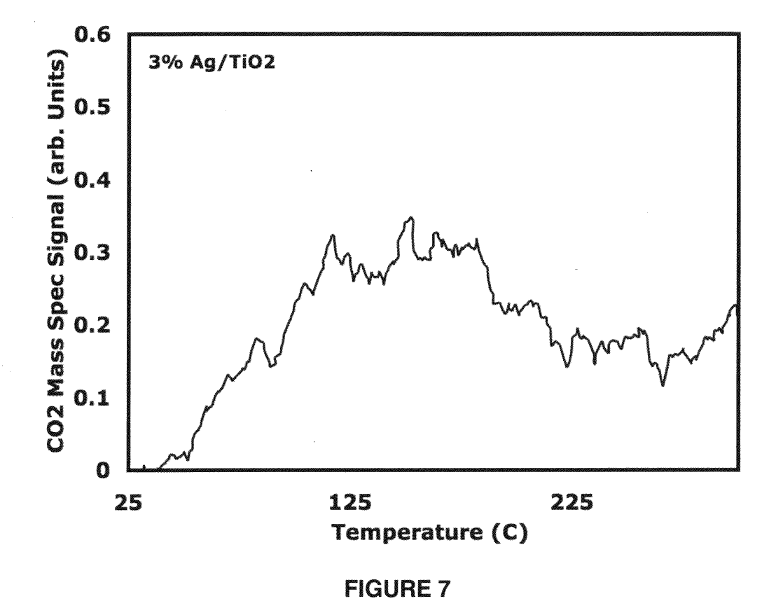

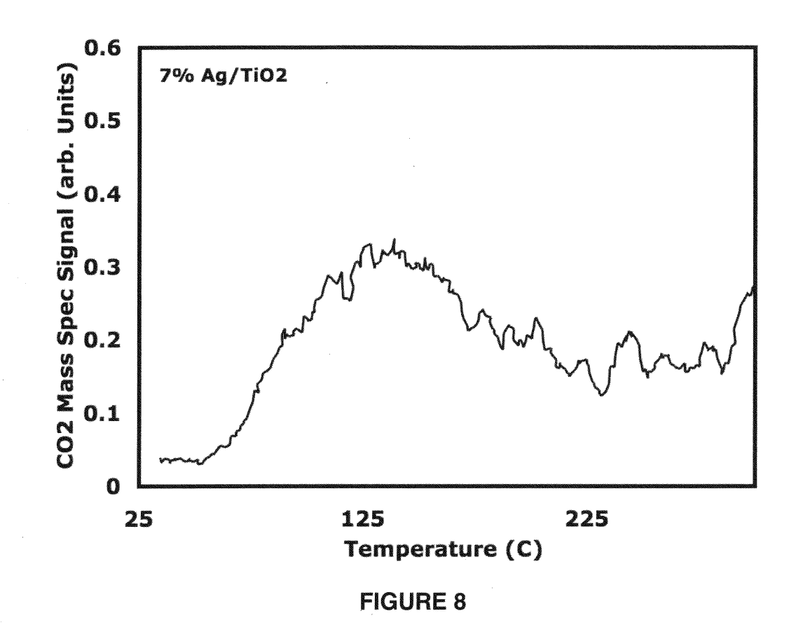

FIGS. 7 and 8 graphically presented the oxidation of carbon monoxide over a temperature range when utilizing photocatalyst compositions according to the invention, and as described in further detail below. Specifically two Ag/TiO₂ composite samples were prepared and tested in a similar manner as above. Spherical silver particles (synthesized using the methods described above) with a peak resonance around 390 nm were used as a test for plasmon enhancement. The samples were prepared by impregnating the TiO₂ with the silver particles in an ethanol solution (standard wet impregnation technique). In a low-loading embodiment, about 3 wt. % silver was present, whereas in a high-loading embodiment, about 7% silver was present. The low-loading embodiment (FIG. 7) showed a broader CO₂ peak at a lower temperature compared to pure TiO₂. The high-loading embodiment (FIG. 8) showed an even lower temperature CO₂ peak when light was added, and showed a very similar activity to pure TiO₂ with no light.

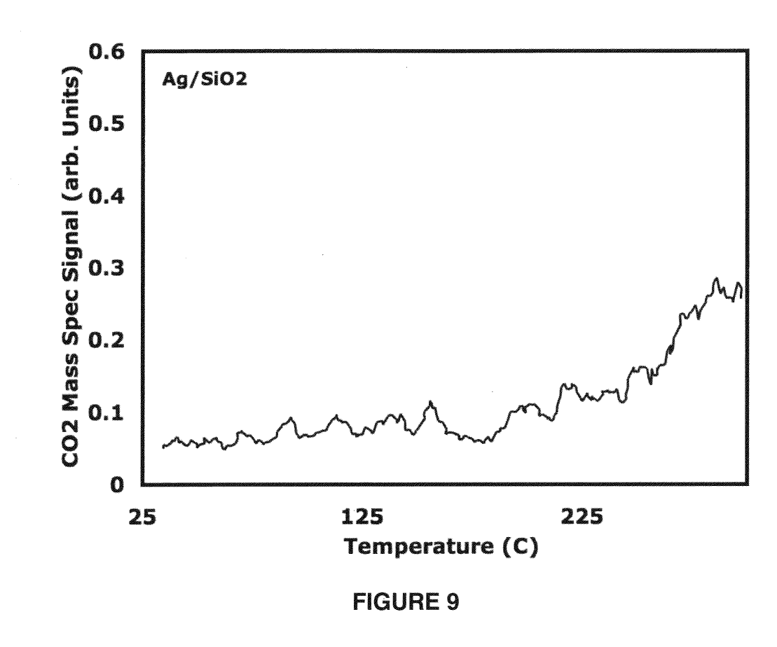

Lastly, a Ag/SiO₂ composition (FIG. 9) was used in the same experiment to ensure that the silver nanoparticles alone are not responsible for the observed enhanced activity. The composition contained about 5% silver.

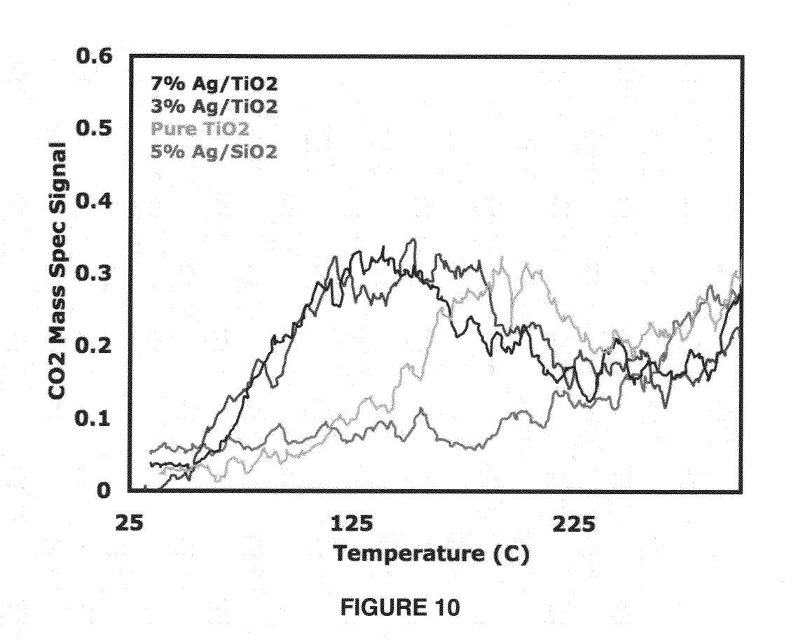

FIG. 10 is a composite of the data present in FIGS. 6 through 9. The data demonstrate that photocatalyst compositions that include (a) a semiconductor, and (b) plasmon-resonating nanoparticles have enhanced activity. The data further demonstrate that the temperature at which the reaction occurs can be reduced by about 80° C. when using such a photocatalyst composition. This is a marked advance over the art, and is expected to result in significant energy savings in processes involving oxidation of carbon monoxide and similar such reactions, which typically require high temperature input.

The foregoing description is given for clearness of understanding only, and no unnecessary limitations should be understood therefrom, as modifications within the scope of the invention may be apparent to those having ordinary skill in the art.

What is claimed is:

1. A photoactive composition comprising:
(a) a semiconductor; and
(b) plasmon-resonating nanoparticles capable of concentrating light at a wavelength that is substantially the same as the wavelength of light necessary to promote an electron from a valance band to a conduction band in the semiconductor.

2. The photoactive composition of claim 1, wherein the light is ultraviolet light.

3. The photoactive composition of claim 1, wherein the light is visible light

4. The photoactive composition of claim 1, wherein the light is infrared light.

5. The photoactive composition of claim 1, wherein the plasmon-resonating nanoparticles comprise at least one of copper, silver, and gold nanoparticles.

6. The photoactive composition of claim 5, wherein the plasmon-resonating nanoparticles comprise copper nanoparticles.

7. The photoactive composition of claim 5, wherein the plasmon-resonating nanoparticles comprise gold nanoparticles.

8. The photoactive composition of claim 5, wherein the plasmon-resonating nanoparticles comprise silver nanoparticles.

9. The photoactive composition of claim 1, wherein the semiconductor is doped.

10. The photoactive composition of claim 1, wherein the semiconductor is selected from the group consisting of ZrO₂, KTaO₃, SrTiO₃, TiO₂, ZnO, ZnS, CdS, CdSe, CdTe, GaP, SiC, Si, MoS₂, WO₃, and Fe₂O₃.

11. The photoactive composition of claim 10, wherein the semiconductor is TiO₂.

12. The photoactive composition of claim 1, wherein the mass ratio of the semiconductor to plasmon-resonating nanoparticles present in the composition is about 4:1 to about 100:1.

13. The photoactive composition of claim 12, wherein the mass ratio is about 5:1 to about 25:1.

14. The photoactive composition of claim 12, wherein the mass ratio is about 8:1 to about 10:1.

15. The photoactive composition of claim 1, wherein the plasmon-resonating nanoparticles have a spherical shape.

16. The photoactive composition of claim 1, wherein the plasmon-resonating nanoparticles have a cube shape.

17. The photoactive composition of claim 1, wherein the plasmon-resonating nanoparticles have a wire shape.

18. The photoactive composition of claim 1, wherein the plasmon-resonating nanoparticles have an effective diameter of about 10 nm to about 200 nm.

19. The photoactive composition of claim 18, wherein the semiconductor absorbs light in a range of about 400-500 nm, and wherein the effective diameter of the plasmon-resonating nanoparticles is about 90 nm to about 150 nm.

20. The photoactive composition of claim 1, wherein plasmon-resonating nanoparticles comprise a non-conductive layer, and wherein the semiconductor is in direct contact with a nonconductive layer.

21. The photoactive composition of claim 20, wherein the semiconductor does not wet the surface of the plasmon-resonating nanoparticles.

22. A photoactive composition comprising:
(a) a semiconductor; and
(b) plasmon-resonating nanoparticles comprising at least one of copper, silver, and gold nanoparticles, and a non-conductive layer, wherein the plasmon-resonating nanoparticles are capable of concentrating light at a wavelength that is substantially the same as the wavelength of light necessary to promote an electron from a valance band to a conduction band in the semiconductor.

23. A photovoltaic device comprising: a front contact, a photoactive composition of claim 1, and a rear contact; wherein the front contact and the rear contact are, separately, electrically connected to the photoactive composition.

24. The photovoltaic device of claim 23, wherein the plasmon-resonating nanoparticles comprise at least one of copper, silver, and gold nanoparticles, and wherein the plasmon-resonating nanoparticles have an effective diameter of about 30 nm to about 200 nm.
